(19) United States
(12) Patent Application Publication
(10) Pub. No.: US 2009/0140379 A1
(43) Pub. Date: Jun. 4, 2009

(54) SEMICONDUCTOR DEVICE AND METHOD FOR FABRICATING THE SAME

(75) Inventor: Dae Young KIM, Suwon-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 12/119,400

(22) Filed: May 12, 2008

(30) Foreign Application Priority Data
Nov. 29, 2007 (KR) 10-2007-0122950

(51) Int. Cl. H01L 21/762; H01L 23/00

(52) U.S. Cl. 257/510; 438/424; 257/E23.002; 257/E21.546

(57) ABSTRACT

A semiconductor device includes a device isolation region formed on a part of shallow trench isolation (STI) sidewalls to relieve stress applied to an active region, thereby improving current flowing toward a channel region.

### CROSS-REFERENCES TO RELATED APPLICATIONS

The priority of Korean patent application number 10-2007-0122950, filed on Nov. 29, 2007, which is incorporated by reference in its entirety, is claimed.

### BACKGROUND OF THE INVENTION

The present invention generally relates to a semiconductor device, and more specifically, to a semiconductor device having a device isolation structure and a method for fabricating the same.

Generally, manufacturers reduce device size to increase operating speed of the semiconductor device such as a transistor. In the case of transistors, if the device size becomes smaller, a breakdown voltage of a source/drain is reduced, junction capacitance is increased, and a short channel effect (SCE) is generated.

Efforts for improving an operating speed of the device has moved from reduction of the device size to improvement of carrier mobility of transistors and reduction of the SCE. The carrier mobility of the transistor is improved by straining the semiconductor device.

In order to improve an operating characteristic of NMOS and PMOS transistors, when stress is applied to the transistor, a tensile stress and a compressive stress are applied to the transistor along a channel direction of the device.

In order to improve the carrier mobility, different types of stress are applied to each transistor depending on the type of transistor. For example, a stress may be regulated depending on spacer materials and deposition conditions when a gate spacer is formed.

Stress can be regulated by adjusting a device isolation structure adjacent to the channel of the device. For example, in a device isolating process for defining an active region, an oxide film is formed on a sidewall of the device isolation structure, and a liner nitride film is formed over the device isolation structure. In some cases, the liner nitride film is removed from some PMOS transistors.

However, current increasing effects in transistors are hindered by the above method because a different stress is applied to the transistor in horizontal and longitudinal directions and the stress is differentiated depending on a distance of the adjacent active region.

### BRIEF SUMMARY OF THE INVENTION

Various embodiments of the present invention are directed at providing a semiconductor device having an improved device isolation structure so that more current may flow through a channel in the same threshold voltage.

Various embodiments of the present invention are directed at preventing a decrease of driving currents due to stress.

According to an embodiment of the present invention, a semiconductor device includes a device insulation region having a liner nitride film formed on a part of sidewalls of a device isolation trench.

The part of the sidewalls may include the sidewalls in a first direction intersected by a longitudinal direction of a gate. The part of the sidewalls may include the sidewalls in a second direction parallel to a longitudinal direction of a gate. The part of the sidewalls may include one of both sidewalls of a first direction intersected by a longitudinal direction of a gate and one of both sidewalls of a second direction intersected by the first direction of the sidewalls surrounding an active region. The part of the sidewalls may exclude one of both sidewalls of a first direction intersected by a longitudinal direction of a gate or one of both sidewalls of a second direction intersected by the first direction of the sidewalls surrounding an active region. The part of sidewalls may include only one sidewall of the sidewalls surrounding an active region. The semiconductor device may be a PMOS transistor.

According to an embodiment of the present invention, a semiconductor device includes a device isolation region having a liner oxide nitride film formed on a part of sidewalls of a device isolation trench.

According to an embodiment of the present invention, a method for fabricating a semiconductor device includes forming a trench in a semiconductor substrate that defines an active region on the semiconductor substrate; forming a liner nitride film on a partial sidewall of the trench; forming a device isolation region over the trench including the liner nitride film; and forming a gate over the active region.

The forming-a-liner-nitride-film step includes: depositing the liner nitride film sidewalls of the trench; and selectively removing the liner nitride film deposited on the other part of the sidewalls of the trench. The liner nitride film is formed by thermal treatment under an atmosphere of NH₃, N₂O and NO. The removing-the-liner-nitride-film step includes: forming a mask for exposing the liner nitride film deposited on the other part of sidewalls which are intersected by a longitudinal direction of the gate; removing the exposed liner nitride film; and removing the mask. The removing-the-liner-nitride-film step includes: forming a mask for exposing the liner nitride film deposited on the other part of the sidewalls which are parallel to a longitudinal direction of the gate; removing the exposed liner nitride film; and removing the mask. The removing-the-liner-nitride-film step includes: forming a mask for exposing the liner nitride film deposited on the other part of the sidewalls which include one of the sidewalls in a longitudinal direction of the gate and one of the sidewalls in a second direction intersected by the first direction; removing the exposed liner nitride film; and removing the mask. The removing-the-liner-nitride-film step includes: forming a mask for exposing the liner nitride film deposited on the other part of sidewalls which include one of the sidewalls in a first direction intersected by a longitudinal direction of the gate or one of the sidewalls in a second direction intersected by the first direction; removing the exposed liner nitride film; and removing the mask. The liner nitride film is removed by dry etching. The liner nitride film is removed by wet etching with H₃PO₄. The device isolation region includes a spin-on-dielectric (SOD) oxide film.

### BRIEF DESCRIPTION OF THE DRAWINGS

FIG. 1 is a diagram illustrating a semiconductor device according to an embodiment of the present invention.

FIGS. 2a to 2h are cross-sectional diagrams illustrating a method for fabricating a semiconductor device according to an embodiment of the present invention.

FIGS. 3a to 3c are cross-sectional diagrams illustrating a method for fabricating a semiconductor device according to an embodiment of the present invention.

FIG. 4 is a cross-sectional diagram illustrating a semiconductor device according to an embodiment of the present invention.

FIG. 5 is a cross-sectional diagram illustrating a semiconductor device according to an embodiment of the present invention.

### DESCRIPTION OF EMBODIMENTS

The present invention relates to a method for fabricating a semiconductor device that includes forming a liner nitride film not entirely on sidewalls of a trench but selectively on a part of the sidewalls to improve a device operating characteristic of a PMOS region.

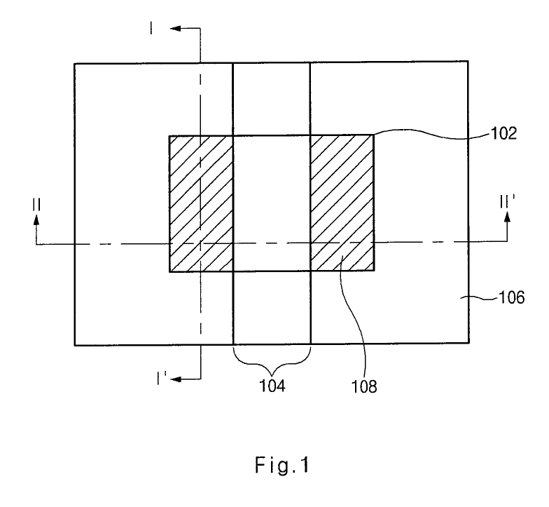

FIG. 1 is a diagram illustrating a semiconductor device according to an embodiment of the present invention.

Referring to FIG. 1, the semiconductor device includes an active region 102, a gate region 104, a device isolation region 106 and a source/drain region 108. The active region 102 is defined by the device isolation region 106. The gate region 104 includes the active region 102 and the device isolation region 106 adjacent to the active region 102. The source/drain region 108 is formed in the active region 102 located at both sides of the gate region 104.

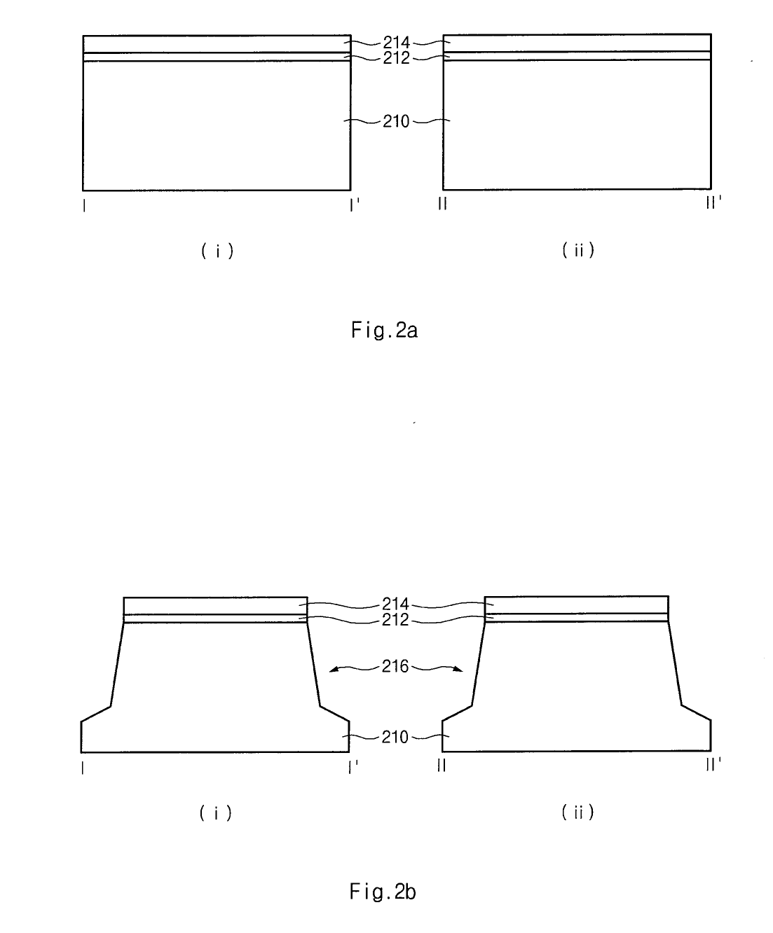

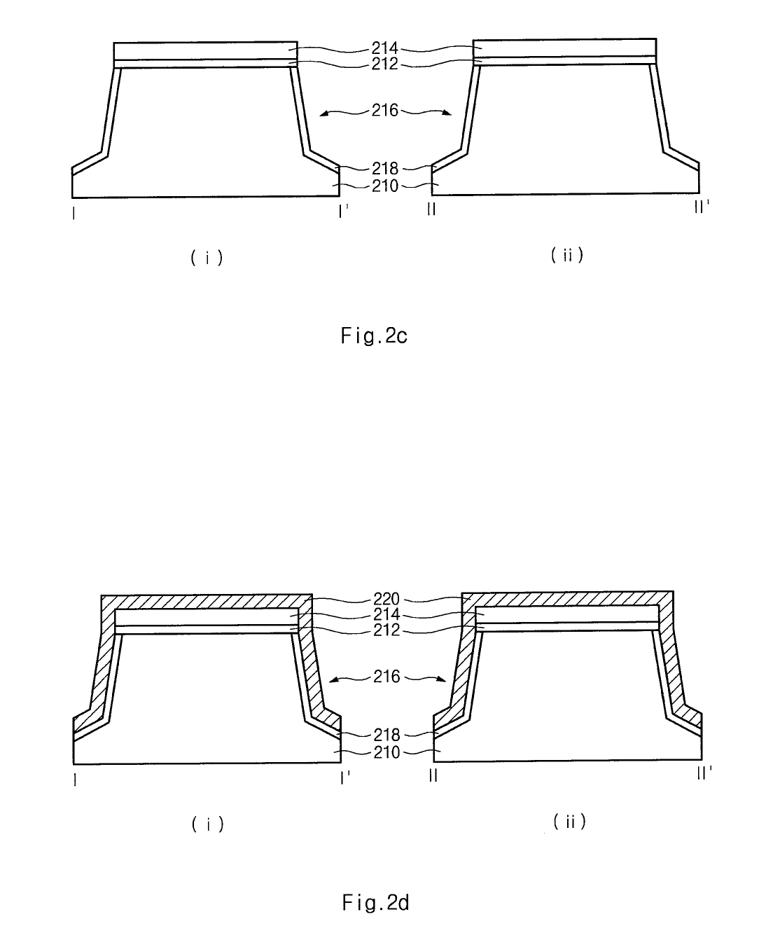

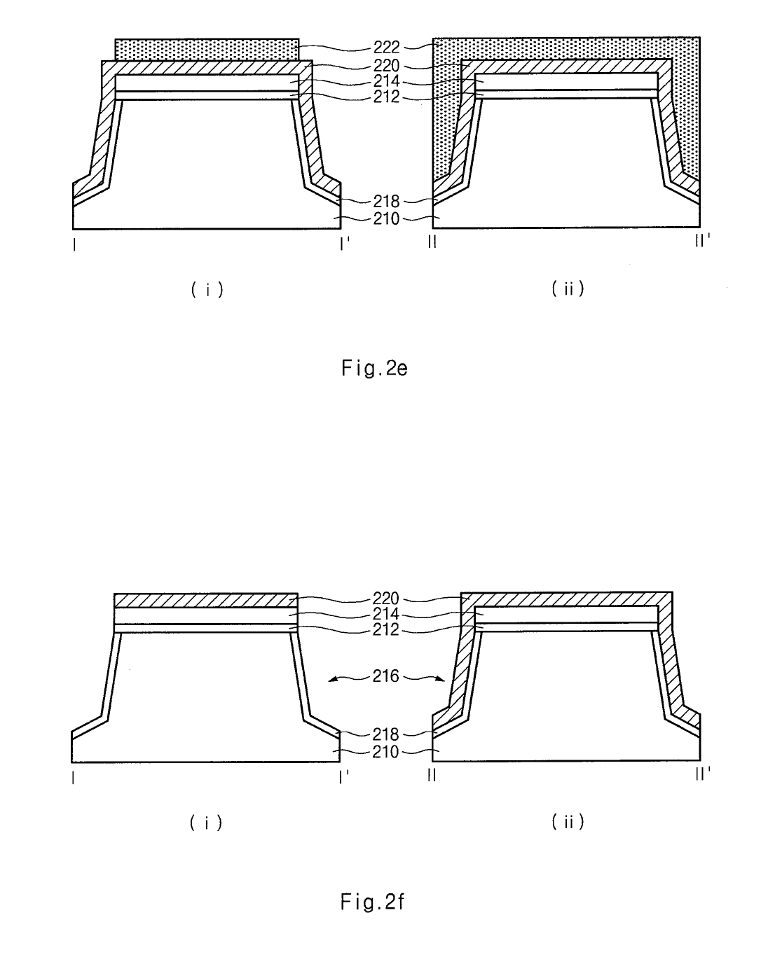

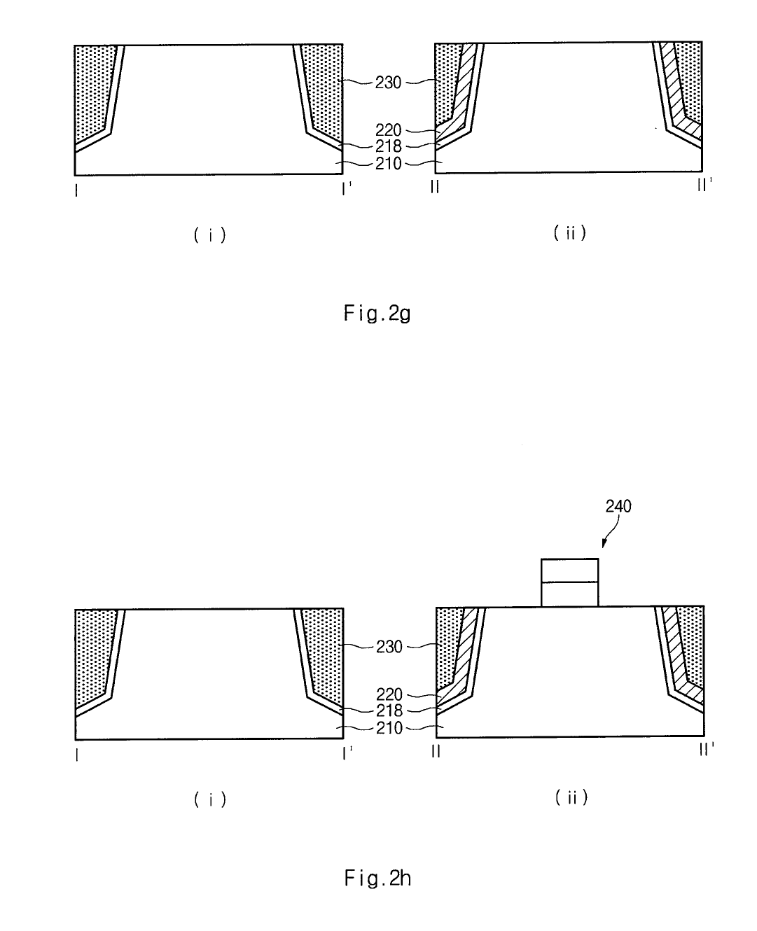

FIGS. 2a to 2h are cross-sectional diagrams illustrating a method for fabricating a semiconductor device according to an embodiment of the present invention. FIGS. 2a(i) to 2g(i) are cross-sectional diagrams taken along I-I′ of FIG. 1, and FIGS. 2a(ii) to 2g(ii) are cross-sectional diagrams taken along II-II′ of FIG. 1.

Referring to FIG. 2a, a pad oxide film 212 and a pad nitride film 214 are sequentially formed over a semiconductor substrate 210.

Referring to FIG. 2b, the pad nitride film 214, the pad oxide film 212 and the semiconductor substrate 210 which correspond to the device isolation region 106 of FIG. 1 are etched to form a trench 216.

Referring to FIGS. 2c and 2d, a sidewall insulating film 218 is formed on sidewalls of the trench 216. The sidewall insulating film 218 may include a thermal oxide film.

A liner nitride film 220 is formed over the resulting structure of FIG. 2c. The liner nitride film 220 is formed by thermal treatment under an atmosphere of NH₃, N₂O and NO. The liner nitride film 220 may be replaced with a liner oxide nitride film.

Referring to FIGS. 2e and 2f, a photoresist film (not shown) is formed over the liner nitride film 220. The photoresist film is partially exposed and developed to form a mask pattern 222 that exposes a part of the liner nitride film 220. The mask pattern 222 exposes the liner nitride film 220 formed on the sidewalls of the trench in a first direction. That is, the mask pattern 222 exposes the liner nitride film 220 formed on the sidewalls in a direction (i.e., horizontal direction in FIG. 1) intersected by a longitudinal direction of the gate region 104 of the active region 102.

The liner nitride film 220 is removed by a dry etching method, a wet etching method or combinations thereof. The wet etching method is performed with H₃PO₄. The mask pattern 222 is then removed.

Referring to FIGS. 2g and 2h, a device isolation insulating film (not shown) is formed over the resulting structure of FIG. 2f to fill the trench 216. The device isolation insulating film includes a spin-on-dielectric (SOD) oxide film, a spin-on-glass (SOG) oxide film, a high density plasma (HDP) oxide film or combinations thereof. The device isolation insulating film includes a SOD oxide film in one embodiment of the present invention.

The device isolation insulating film is planarized until the semiconductor substrate 210 is exposed to form a device isolation region 230. A gate 240 is then formed over the semiconductor substrate 210.

A liner nitride film is not formed on the sidewalls of the trench in the first direction. That is, a liner nitride film is formed only on sidewalls located on opposite sides of the gate region 104.

The device isolation structure according to the embodiment of the present invention is formed in a PMOS region.

In accordance with embodiments of the invention, although the sidewall in the first direction is formed with a straight line in FIG. 1, it is not limited herein.

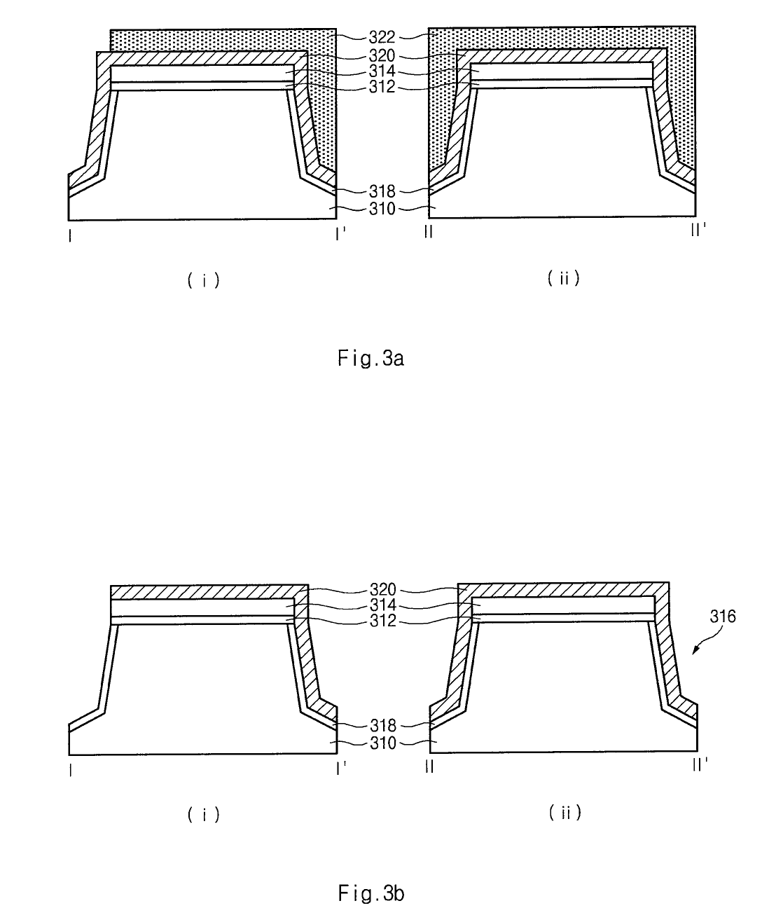

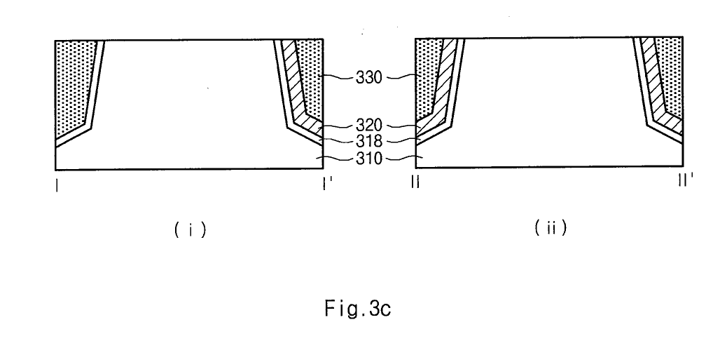

FIGS. 3a to 3c are cross-sectional diagrams illustrating a method for fabricating a semiconductor device according to an embodiment of the present invention. FIGS. 3a(i) to 3g(i) are cross-sectional diagrams taken along I-I′ of FIG. 1, and FIGS. 3a(ii) to 3g(ii) are cross-sectional diagrams taken along II-II′ of FIG. 1.

Referring to FIG. 3a, a photoresist film (not shown) is formed over the resulting structure formed by the processes of FIGS. 2a to 2d.

The photoresist film is partially exposed and developed to form a mask pattern 322 that exposes a part of the liner nitride film 320. The mask pattern 322 exposes the liner nitride film 320 formed on one of the trench sidewalls in a first direction.

Referring to FIG. 3b, the exposed liner nitride film 320 is removed by a dry etching method, a wet etching method or combinations thereof. The wet etching method is performed with H₃PO₄. The mask pattern 322 is then removed.

Referring to FIG. 3c, a device isolation insulating film (not shown) is formed over the resulting structure of FIG. 3b to fill the trench. The device isolation insulating film includes a spin-on-dielectric (SOD) oxide film, a spin-on-glass (SOG) oxide film, a high density plasma (HDP) oxide film or combinations thereof. The device isolation insulating film includes a SOD oxide film in one embodiment of the present invention. The device isolation insulating film is planarized until the semiconductor substrate 310 is exposed to form a device isolation region 330.

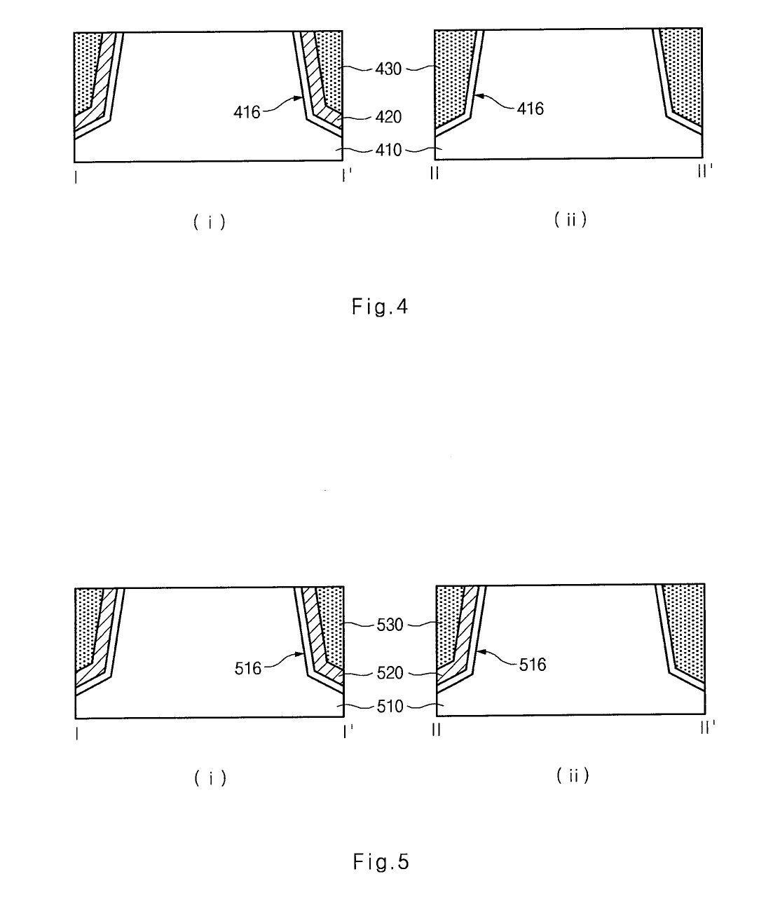

FIG. 4 is a cross-sectional diagram illustrating a semiconductor device according to an embodiment of the present invention. FIG. 4(i) is a cross-sectional diagram taken along I-I′ of FIG. 1, and FIG. 4(ii) is a cross-sectional diagram taken along II-II′ of FIG. 1.

In comparison with FIG. 2g, a liner nitride film 420 is not formed on trench sidewalls 416 (i.e., sidewalls located at both sides of the gate region 104) in a second direction intersected by the first direction. That is, in one embodiment of the present invention, a liner nitride film is formed only on the sidewalls 416 in the first direction.

The semiconductor device of FIG. 4 may be fabricated by the method of FIGS. 2a to 2h except that a mask pattern is formed to expose the liner nitride film 420 not in the first direction but in the second direction.

FIG. 5 is a cross-sectional diagram illustrating a semiconductor device according to an embodiment of the present invention. FIG. 5(i) is a cross-sectional diagram taken along I-I′ of FIG. 1, and FIG. 5(ii) is a cross-sectional diagram taken along II-II′ of FIG. 1.

In comparison with FIG. 3c, a liner nitride film 420 is not formed on one of trench sidewalls 516 (i.e., sidewalls located at both sides of the gate region 104) in a second direction.

The liner nitride film is not formed on one of the trench sidewalls 516 in the first direction or the second direction. For example, a liner nitride film may be formed on one both sidewalls 516 in the first direction and on only one of the sidewalls 516 in the second direction.

The liner nitride film may be formed on only one of the trench sidewalls surrounding each active region 102.

As described above, according to an embodiment of the present invention, a nitride film is formed selectively on trench sidewalls to improve carrier mobility and prevent current reduction due to stress, thereby improving characteristics of the device.

The above embodiments of the present invention are illustrative and not limitative. Various alternatives and equivalents are possible. The invention is not limited by the type of deposition, etching polishing, and patterning steps described herein. Nor is the invention limited to any specific type of semiconductor device. For example, the present invention may be implemented in a dynamic random access memory (DRAM) device or non-volatile memory device. Other additions, subtractions, or modifications are obvious in view of the present disclosure and are intended to fall within the scope of the appended claims.

What is claimed is:

1. A semiconductor device comprising a device insulation region having a liner nitride film formed over a part of sidewalls of a device isolation trench.

2. The semiconductor device according to claim 1, wherein the part of sidewalls include the sidewalls in a first direction intersected by a longitudinal direction of a gate.

3. The semiconductor device according to claim 1, wherein the part of sidewalls include the sidewalls in a second direction parallel to a longitudinal direction of a gate.

4. The semiconductor device according to claim 1, wherein the part of sidewalls include one of both sidewalls in a first direction intersected by a longitudinal direction of a gate and one of both sidewalls in a second direction intersected by the first direction.

5. The semiconductor device according to claim 1, wherein the part of sidewalls exclude one of both sidewalls in a first direction intersected by a longitudinal direction of a gate or one of both sidewalls in a second direction intersected by the first direction.

6. The semiconductor device according to claim 1, wherein the part of sidewalls include only one sidewall.

7. The semiconductor device according to claim 1, wherein the semiconductor device is a PMOS transistor.

8. A semiconductor device comprising a device isolation region having a liner oxide nitride film formed over a part of sidewalls of a device isolation trench.

9. A method for fabricating a semiconductor device, the method comprising:
forming a trench in a semiconductor substrate, wherein the trench defines an active region in the semiconductor substrate, the trench having sidewalls;
forming a liner nitride film over a part of the sidewalls of the trench;
forming a device isolation region over the trench including the liner nitride film; and
forming a gate over the active region.

10. The method according to claim 9, wherein the forming-a-liner-nitride-film step includes:
depositing the liner nitride film over the sidewalls of the trench; and
selectively removing the liner nitride film deposited over the other part of the sidewalls of the trench.

11. The method according to claim 10, wherein the liner nitride film is formed by thermal treatment in an atmosphere of NH₃, N₂O and NO.

12. The method according to claim 10, wherein the removing-the-liner-nitride-film step includes:
forming a mask for exposing the liner nitride film deposited over the other part of the sidewalls which are intersected by a longitudinal direction of the gate;
removing the exposed liner nitride film; and
removing the mask.

13. The method according to claim 10, wherein the removing-the-liner-nitride-film step includes:
forming a mask for exposing the liner nitride film deposited over the other part of the sidewalls which are parallel to a longitudinal direction of the gate;
removing the exposed liner nitride film; and
removing the mask.

14. The method according to claim 10, wherein the removing-the-liner-nitride-film step includes:
forming a mask for exposing the liner nitride film deposited over the other part of the sidewalls which include one of the sidewalls in a longitudinal direction of the gate and one of the sidewalls in a second direction intersected by the first direction;
removing the exposed liner nitride film; and
removing the mask.

15. The method according to claim 10, wherein the removing-the-liner-nitride-film step includes:
forming a mask for exposing the liner nitride film deposited over the other part of the sidewalls which include one of the sidewalls in a first direction intersected by a longitudinal direction of the gate or one of the sidewalls in a second direction intersected by the first direction;
removing the exposed liner nitride film; and
removing the mask.

16. The method according to claim 10, wherein the liner nitride film is removed by dry etching.

17. The method according to claim 10, wherein the liner nitride film is removed by wet etching with H₃PO₄.

18. The method according to claim 9, wherein the device isolation region includes a spin-on-dielectric (SOD) oxide film.
